(19) United States
(12) Patent Application Publication
(10) Pub. No.: US 2007/0008041 A1
(43) Pub. Date: Jan. 11, 2007

(54) Layout for a time base

(76) Inventor: David Ruffieux, Lugnorre (CH)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/556,909

(22) PCT Filed: May 12, 2004
(86) PCT No.: PCT/CH04/00288

§ 371 Date: Nov. 15, 2005

(30) Foreign Application Priority Data
May 15, 2003 (FR) 0305834

(51) Int. Cl. H03L 7/00

(52) U.S. Cl. 331/16

(57) ABSTRACT

Time base including two oscillators, one of which has a lower frequency than the other, the latter being intermittently set to standby mode, generating according to the same intermittency a first stable time reference (REF) by difference between the frequencies of the two oscillators, a second permanent time reference (RTC) being obtained by division of the frequency of the oscillator having the lowest frequency and the division factor being dependent on the pulses counted for the first oscillator (OSC1) during a time interval determined by the first stable time reference (REF).

This application is a national stage filing under 35 U.S.C. §371 of International Application No. PCT/CH2004/000288, filed on May 12, 2004.

### TECHNICAL FIELD

The invention relates to a layout, in particular for a timepiece time base, intended to generate a time reference, and to a method of generating a time reference.

### BACKGROUND INFORMATION

### SUMMARY OF THE INVENTION

an oscillator circuit including a second oscillator including and a silicon resonator, the frequency F₂ of which is different from that of the resonator of the first oscillator, and which presents a first order thermal coefficient in a ratio λ.F₁₀/F₂₀ with the first order thermal coefficient of the resonator of the first oscillator, F₁₀ and F₂₀ being the respective natural frequencies of the first and second resonators,
the oscillator circuit also including a frequency divider dividing the frequency F₂ of the signal output by the second oscillator by a factor λ and generating the output signal of this oscillator circuit,
means for generating, by frequency difference between the signal output by the first oscillator and the signal output by the second oscillator circuit, a first temperature-stable time reference,
the correction means include includes a programmable frequency divider having a range of division factors with which to compensate the frequency drifts of the first oscillator due to the temperature and/or the absolute accuracy of the first oscillator.
the second oscillator includes a silicon resonator, the first order thermal coefficient of which is in a ration λ.F₁/F₂ with the first order thermal coefficient of the first oscillator, and a frequency divider dividing the frequency F₂ of the signal output by this resonator by a factor λ and generating the output signal of the second oscillator.
generation of a second frequency, different from the first frequency by a second oscillator including a silicon resonator, the first order thermal coefficient of the resonator of the first oscillator being roughly equal to the first order thermal coefficient of the resonator of the second oscillator multiplied by the ratio F₂₀/λ.F₁₀,
generation of a first temperature-stable time reference by frequency difference between the signal output by the first oscillator and the signal output by the second oscillator, after division of the latter by the factor λ,

### BRIEF DESCRIPTION OF THE DRAWINGS

### Detailed Description

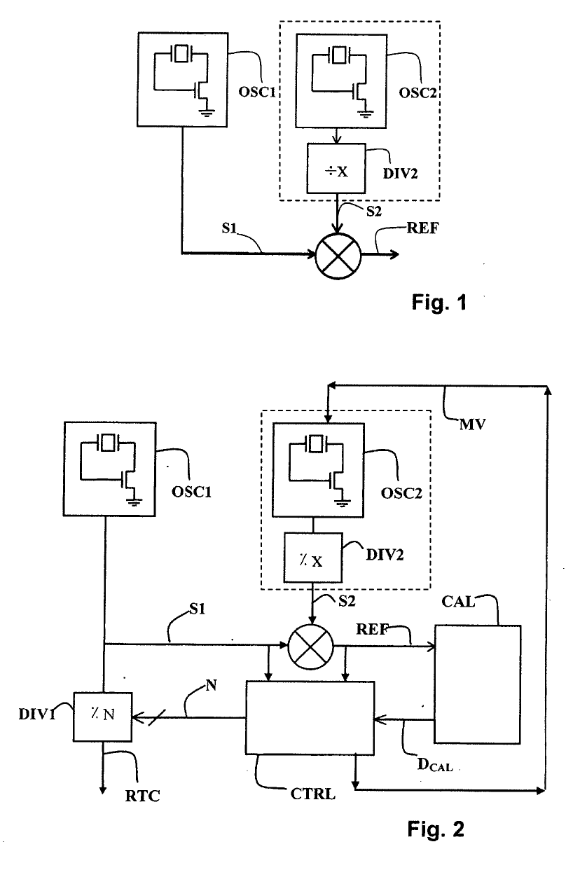

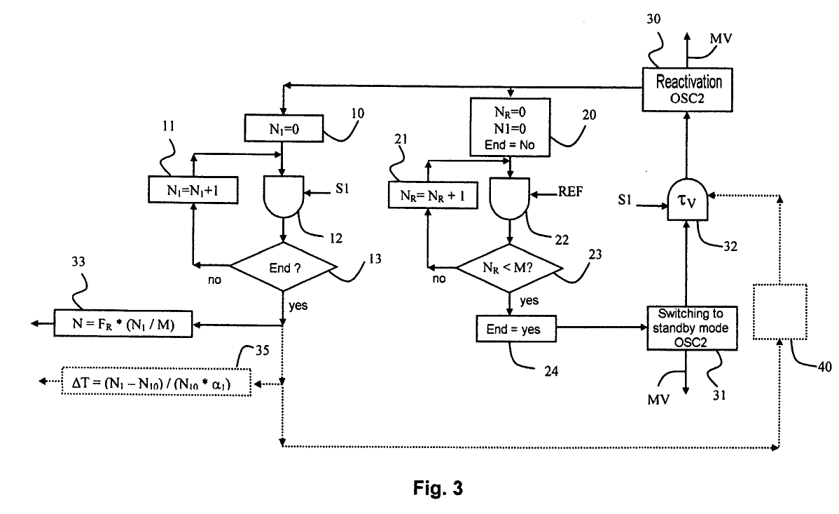

FIG. 1 represents a an exemplary schematic diagram of a time base using the frequency difference of the signals from two oscillators, each including a silicon resonator. In this figure, the first oscillator OSC1 operates at a lower frequency than the oscillator OSC2. At the output of the second oscillator, there is a frequency divider DIV2, associated with the second oscillator OSC2 and performing a frequency division by an integer number λ. These two components together define an oscillator circuit (symbolized by broken lines in FIGS. 1 and 2). The frequency difference between the signal S1 from the first oscillator OSC1 and the signal S2 from the second oscillator OSC2, after frequency division by a factor λ, forms a time reference REF, the. The frequency of which is stable, if the ratio between the frequencies is the inverse of the ratio of their first order thermal coefficient.

ΔT being a temperature variation, α₁ being the first order thermal coefficient of the resonator of the oscillator OSC1 and F₁₀ being its natural frequency,

α₂ being the first order thermal coefficient of the resonator of the oscillator OSC2 and F₂₀ being its natural frequency, and also, the following condition is satisfied:

What is claimed is:

1-12. (canceled)

13. A layout, delivering an output signal intended to form a time reference, including:
first oscillator, including a silicon resonator of frequency F₁ and of natural frequency F₁₀, generating an output signal, said resonator having a first order thermal coefficient α₁;
an oscillator circuit including a second oscillator, said second oscillator outputting a signal and including a silicon resonator of frequency F₂ different from that of said resonator of said first oscillator and of natural frequency F₂₀;
said resonator of said second oscillator presenting a first order thermal coefficient α₂ in a ratio λ.F₁₀/F₂₀ with said first order thermal coefficient α₁, λ being a proportionality factor, and said oscillator circuit also including a frequency divider dividing said frequency F₂ of said signal output of said second oscillator by said factor λ and generating an output signal of said oscillator circuit;
means for generating, by frequency difference between said signal output by said first oscillator and said signal output by said oscillator circuit, a first temperature-stable time reference;
means for determining a frequency drift due to the temperature of said signal output by said first oscillator by comparing the signal output with said first temperature-stable time reference; and
programmable correction means which, according to the value of said drift, divide the frequency of said signal output by said first oscillator and generate said layout output signal forming a second temperature-stable time reference.

14. The layout according to claim 13, further including:
means for counting, during a counting phase and over a predetermined number of cycles of said first time reference, a number of pulses generated by said first oscillator; and
means for determining said frequency drift and controlling said programmable correction means according to said number of pulses counted and said number of cycles of said first time reference during which counting was enabled.

15. The layout according to claim 14, further including:
means of selecting a standby mode for intermittently setting said second oscillator to the standby mode, wherein said counting phase runs during a phase of activity of said second oscillator.

16. The layout according to claim 15, wherein said means of selecting a standby mode includes means for varying the time interval between two successive phases of activity, according to the accuracy required for said second time reference and/or to said number of pulses counted for said first oscillator in at least one of the preceding counting phases.

17. The layout according to claim 14, further including means for generating temperature information from said number of pulses generated by said first oscillator in said counting phase.

18. The layout according to claim 15, further including means for generating temperature information from said number of pulses generated by said first oscillator in said counting phase.

19. The layout according to claim 16, further including means for generating temperature information from said number of pulses generated by said first oscillator in said counting phase.

20. The layout according to claim 13, further including means for storing calibration information concerning the first temperature-stable time reference.

21. The layout according to claim 14, further including means for storing calibration information concerning the first temperature-stable time reference.

22. The layout according to claim 17, further including means for storing calibration information concerning the first temperature-stable time reference

23. The layout according to claim 13, wherein said correction means includes a programmable frequency divider having a range of division factors with which to compensate the frequency drifts of said first oscillator due to the temperature and/or the absolute accuracy of the first oscillator.

24. The layout according to claim 17, wherein said correction means includes a programmable frequency divider having a range of division factors with which to compensate the frequency drifts of said first oscillator due to the temperature and/or the absolute accuracy of the first oscillator.

25. The layout according to claim 22, wherein said correction means includes a programmable frequency divider having a range of division factors with which to compensate the frequency drifts of said first oscillator due to the temperature and/or the absolute accuracy of the first oscillator.

26. A time base including a layout according to claim 13.

27. A thermometer including a layout according to claim 17.

28. A thermometer including a layout according to claim 22.

29. A thermometer including a layout according to claim 25.

30. A timepiece including a layout according to claim 13.

31. A timepiece including a layout according to claim 17.

32. A method of generating a signal intended to form a time reference including:
generating a first output signal of a first frequency F₁ by a first oscillator including a silicon resonator of natural frequency F₁₀ and of first order thermal coefficient α₁;
generating a signal of a second frequency F₂, different from said first frequency, by a second oscillator including a silicon resonator of natural frequency F₂₀ and which presents a first order thermal coefficient α₂ in a ratio λ.F₁₀/F₂₀ with said first order thermal coefficient α₁, λ being a proportionality factor;
dividing said second frequency F₂ of said signal output by said second oscillator by said factor λ, to generate a second output signal;
generating a first temperature-stable time reference by frequency difference between said first signal output by said first oscillator and said second output signal;
determining, by comparison of said signal output by said first oscillator with said first time reference, the frequency drift due to the temperature of said signal output by said first oscillator; and
correcting, according to the value of said drift, said frequency of said signal by said first oscillator to generate said signal forming a second time reference.
